(19) United States
(12) Patent Application Publication
(10) Pub. No.: US 2009/0091543 A1
(43) Pub. Date: Apr. 9, 2009

(54) Handheld Electronic Devices Supporting Operation as a Musical Instrument with Touch Sensor Input and Methods and Computer Program Products for Operation of Same

(75) Inventors: William O. Camp, Jr., Chapel Hill, NC (US); Toby John Bowen, Durham, NC (US)

Correspondence Address: MYERS BIGEL SIBLEY & SAJOVEC, P.A., P.O. BOX 37428, RALEIGH, NC, 27627, US

(73) Assignee: Sony Ericsson Mobile Communications AB

(21) Appl. No.: 11/941,285

(22) Filed: Nov. 16, 2007

Related U.S. Application Data
(60) Provisional application No. 60/978,202, filed on Oct. 8, 2007.

(51) Int. Cl. G06F 3/041; H03G 3/00

(52) U.S. Cl. 345/173; 381/104

(57) ABSTRACT

A handheld electronic device, such as a mobile terminal, a personal digital assistant, an ultraportable computer and/or a media player, includes a touch sensor, such as a sensor used for fingerprint sensing. A control circuit of the device is configured to support user operation of the handheld electronic device as a musical instrument that uses the touch sensor as a control input of the musical instrument. For example, the control circuit may be configured to dynamically alter an audio signal produced by the musical instrument responsive to contact with the touch sensor, e.g., to control a tone and/or a volume of the audio signal. For example, the control circuit may be configured to cause the handheld electronic device to emulate a stringed instrument wherein contact with the touch sensor corresponds to contact with the strings of the emulated stringed instrument.

### REFERENCE TO PRIORITY APPLICATION

This application claims priority to U.S. Provisional Application No. 60/978,202, filed Oct. 8, 2007, the disclosure of which is hereby incorporated herein by reference.

### FIELD OF THE INVENTION

This invention relates to handheld electronic devices, such as mobile terminals, productivity and entertainment devices and, more particularly, to applications for such devices.

### BACKGROUND OF THE INVENTION

Handheld electronic devices, such as cellular telephones, personal digital assistants (PDAs) and multimedia devices (e.g., iPod® and MP3 players), are now ubiquitous. Such devices are commonly used for a wide variety of personal applications, including, but not limited to, voice communications, instant messaging, email, productivity tools, web browsing, electronic gaming, digital photography and audio and video entertainment. Some devices, such as “smartphones,” provide several of these capabilities in a single device.

### SUMMARY OF THE INVENTION

According to some embodiments of the present invention, an electronic device, such as a mobile terminal, a personal digital assistant, an ultraportable computer and/or a media player, includes a case configured to be supported in a user's hand while the device is in use. A touch sensor, such as a sensor used for fingerprint sensing, is mounted on the case. A control circuit is supported by the case and configured to provide a user interface and to support user applications via the user interface. The control circuit is further configured to support user operation of the handheld electronic device as a musical instrument that uses the touch sensor as a control input of the musical instrument. For example, the control circuit may be configured to dynamically alter an audio signal produced by the musical instrument responsive to contact with the touch sensor, e.g., to control a tone and/or a volume of the audio signal. For example, the control circuit may be configured to cause the handheld electronic device to emulate a stringed instrument wherein contact with the touch sensor corresponds to contact with the strings of the emulated stringed instrument.

In further embodiments, the device further includes a touch-sensitive display electrically coupled to the control circuit. The control circuit is further configured to support user operation of the handheld electronic device as a musical instrument that uses the touch sensor and the touch-sensitive display as control inputs for the musical instrument. For example, the control circuit may be configured to generate a graphical emulation of a control interface of a musical instrument on the touch-sensitive display and to generate an audio signal responsive to contact with the touch-sensitive display in relation to the graphical representation.

Further embodiments of the present invention provide methods of operating a handheld electronic device that provides user applications via a user interface that includes a touch sensor, wherein the handheld electronic device is operated as a musical instrument that uses the touch sensor as a control input of the musical instrument. Additional embodiments provide computer program products for operating a handheld electronic device, the computer program product including program code configured to support user applications via a user interface that includes a touch sensor of the handheld electronic device and program code configured to support operation of the handheld electronic device as a musical instrument that uses the touch sensor as a control input of the musical instrument.

### BRIEF DESCRIPTION OF THE DRAWINGS

FIGS. 1 and 2 are schematic diagrams illustrating a mobile communications terminal with a musical instrument capability according to some embodiments of the present invention.

FIG. 3 is a block diagram illustrating a musical instrument application for a handheld electronic device, such as the device of FIGS. 1 and 2, according to further embodiments of the present invention.

FIG. 4 is a schematic diagram illustrating emulation of a stringed instrument by the device of FIGS. 1 and 2 according to some embodiments of the present invention.

FIG. 5 is a schematic diagram illustrating emulation of a keyboard instrument by the device of FIGS. 1 and 2 according to some embodiments of the present invention.

### DETAILED DESCRIPTION

The present invention now will be described more fully hereinafter with reference to the accompanying figures, in which embodiments of the invention are shown. This invention may, however, be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,” “includes” and/or “including” (and variants thereof) when used in this specification, specify the presence of stated features, integers, steps, operations, elements, and/or components, but do not preclude the presence or addition of one or more other features, integers, steps, operations, elements, components, and/or groups thereof. Moreover, when an element is referred to as being “responsive” to another element/step (and variants thereof), it can be directly responsive to the other element/step, or intervening elements/steps may be present. In contrast, when an element/step is referred to as being “directly responsive” to another element/step (and variants thereof), there are no intervening elements/steps present. As used herein the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another.

The present invention is described below with reference to schematic diagrams illustrating methods, apparatus (systems and/or devices) and/or computer program products according to embodiments of the invention. It is understood that a block of the diagrams, and combinations of blocks in the diagrams can be implemented by computer program instructions. These computer program instructions may be provided to a processor of a general purpose computer, special purpose computer, and/or other programmable data processing apparatus to produce a machine, such that the instructions, which execute via the processor of the computer and/or other programmable data processing apparatus, create means (functionality) and/or structure for implementing the functions/acts specified in the diagrams. These computer program instructions may also be stored in a computer-readable memory that can direct a computer or other programmable data processing apparatus to function in a particular manner, such that the instructions stored in the computer-readable memory produce an article of manufacture including instructions which implement the function/act as specified in the diagrams. The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions/acts specified in the diagrams.

Accordingly, the present invention may be embodied in hardware and/or in software (including firmware, resident software, micro-code, etc.). Furthermore, the present invention may take the form of a computer program product on a computer-usable or computer-readable storage medium having computer-usable or computer-readable program code embodied in the medium for use by or in connection with an instruction execution system. In the context of this document, a computer-usable or computer-readable medium may be any medium that can contain, store, communicate or transport the program for use by or in connection with the instruction execution system, apparatus, or device.

The computer-usable or computer-readable medium may be, for example, an electronic, magnetic, optical, electromagnetic or semiconductor system, apparatus or device. More specific examples (a non-exhaustive list) of the computer-readable medium would include the following: a portable computer diskette, a random access memory (RAM), a read-only memory (ROM), an erasable programmable read-only memory (EPROM or Flash memory), and a portable optical and/or magnetic media, such as a flash disk or CD-ROM.

Some embodiments of the present invention arise from a realization a handheld electronic device, for example, a mobile terminal, personal digital assistant (PDA), multimedia device (e.g. iPod® or MP3 player) or ultraportable computer, may be configured to operate as a musical instrument, and that a touch sensor, such as a fingerprint transducer, of the device may be used to provide control inputs to the musical instrument. For example, in some embodiments, contact with the touch sensor may be used to control volume and/or tone. Various types of contact with the touch sensor may be used to emulate inputs to a musical instrument, such as plucking or strumming of a string, and/or to provide musical effects, such as warping or vibrato.

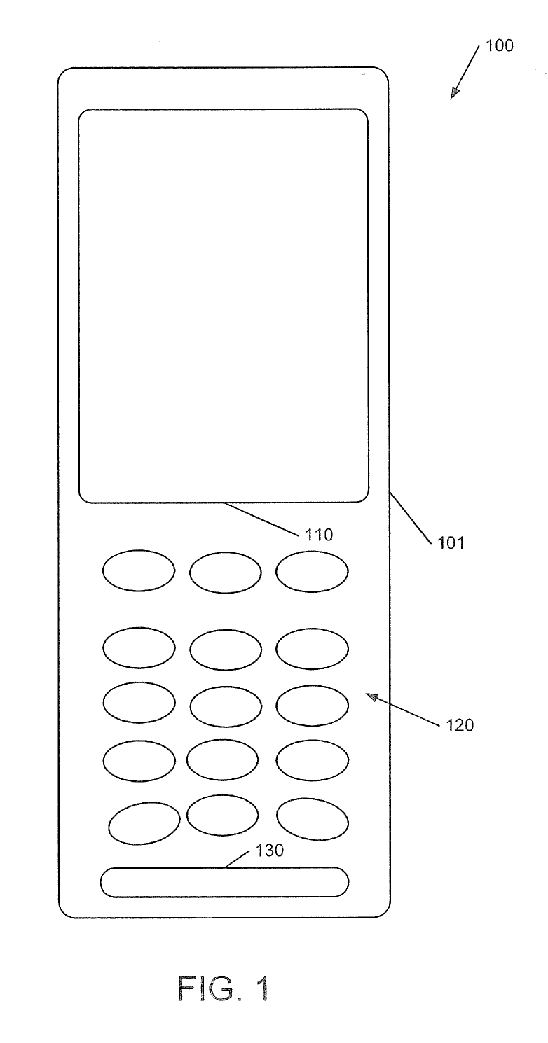

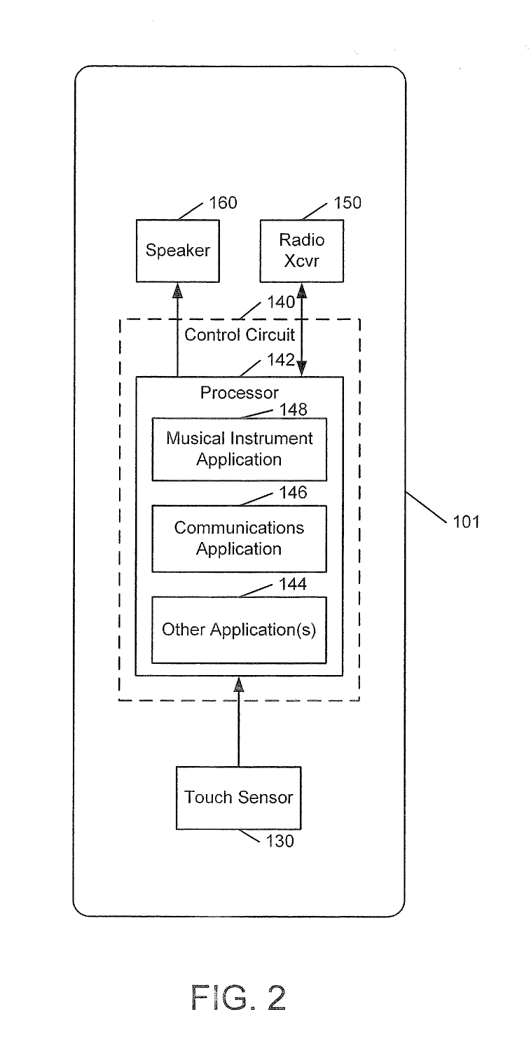

FIGS. 1 and 2 illustrate a mobile terminal 100 according to some embodiments of the present invention. The terminal 100 may be, for example, a “smartphone,” i.e., a radiotelephone terminal that provides additional functionality, such as email, web browsing, productivity applications and the like. Referring to FIG. 1, the terminal 100 includes user interface components, including a display 110, keypad 120 and touch sensor 130. The touch sensor 130 may be, for example, a capacitive sensor of the type that is commonly used for fingerprint identification.

Referring to FIG. 2, the terminal 100 further includes a control circuit 140, illustrated in FIG. 2 as including a processor 142 (e.g., a microprocessor, digital signal processing chip, or other processing device) that is configured to execute program instructions that provide one or more communications applications 146, such as telephony and internet connectivity applications, that utilize a radio transceiver 150. The radio transceiver 150 may support any of a number of different radio interfaces, including, but not limited to, cellular, WiFi and Bluetooth®. The processor 142 may be configured to provide other types of personal applications 144, such as productivity (e.g., calendars, word processors, spread sheets, etc), audio and/or video applications.

The processor 142 is further configured to execute program instructions to provide a musical instrument application 148 that operate responsive to control inputs provided from the touch sensor 130. For example, the musical instrument application 148 may be operative to cause the processor 142 to generate an audio signal responsive to a sense signal generated by the touch sensor 130. The audio signal may, for example, be a digital audio signal that may be converted to an analog signal, amplified and output via speaker 160 of the terminal and/or communicated to an external device, such as an amplifier, recording device, computer, sound system or the like, via the radio transceiver 150 or other external interface.

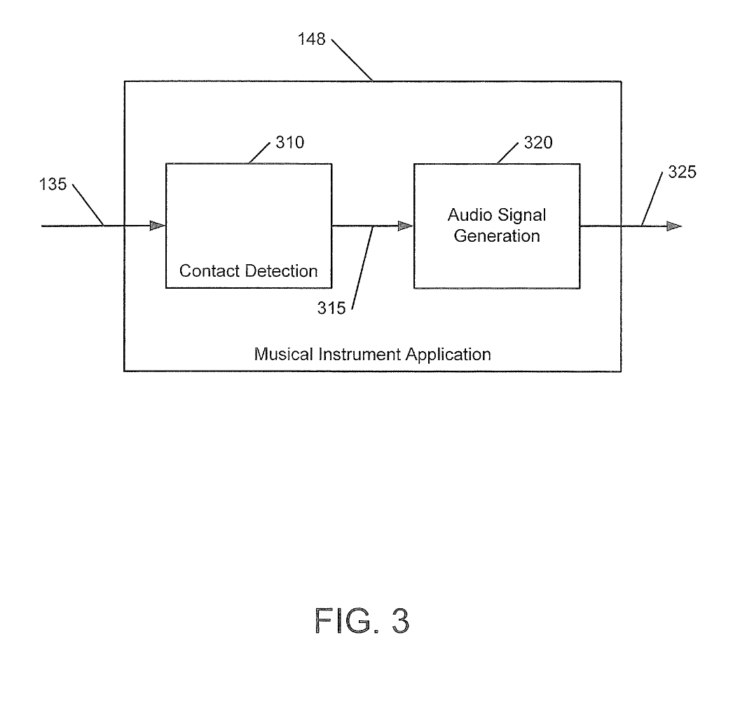

FIG. 3 illustrates an example of a musical instrument application 148 according to some embodiments of the present invention. In the illustrated embodiments, the musical instrument application 148 includes a contact detection component (e.g., module, object, etc.) 310 that receives a sense signal 135 produced by the touch sensor 130 and responsively produces a control signal 315 that is provided to an audio signal generation component 320. The audio signal generation component responsively generates an audio signal 325.

The contact detection component 310 may map information content in the sense signal 135 to various parameters of the audio signal, such as frequency, tone, volume and the like. The contact detection component 310 may, for example, map features of the sense signal 135 that correspond to various geometric characteristics of the contact, such as the spatial arrangement of areas of contact that may be associated with particular shapes and/or surface features, to various characteristics of the audio signal 325. The contact detection component 310 may also, for example, map particular features of the sense signal 135 associated with dynamic characteristics of the contact, such as duration and/or frequency of contact, to various features of the audio signal 325. It will be appreciated that these mappings may be adaptive and/or user-selectable, e.g., a user may select particular mappings that support various instrument paradigms, such as “piano,” “organ,” “vibes,” and the like.

It will be appreciated that the implementations illustrated in FIGS. 2 and 3 are provided for purposes of illustration, and that the present invention is not limited thereto. For example, it will be appreciated that some or all of the functions of the musical instrument application 148 may be realized using circuitry other than a processor, for example, using special-purpose digital and/or analog circuitry, such as an application specific integrated circuit (ASIC). It will be further appreciated that the present invention is not limited to mobile terminals, and may be implemented in other types of handheld electronic devices, such as PDAs, media player devices (e.g., iPod® and MP3 players) and ultraportable computers (e.g., tablet and subnotebook computers).

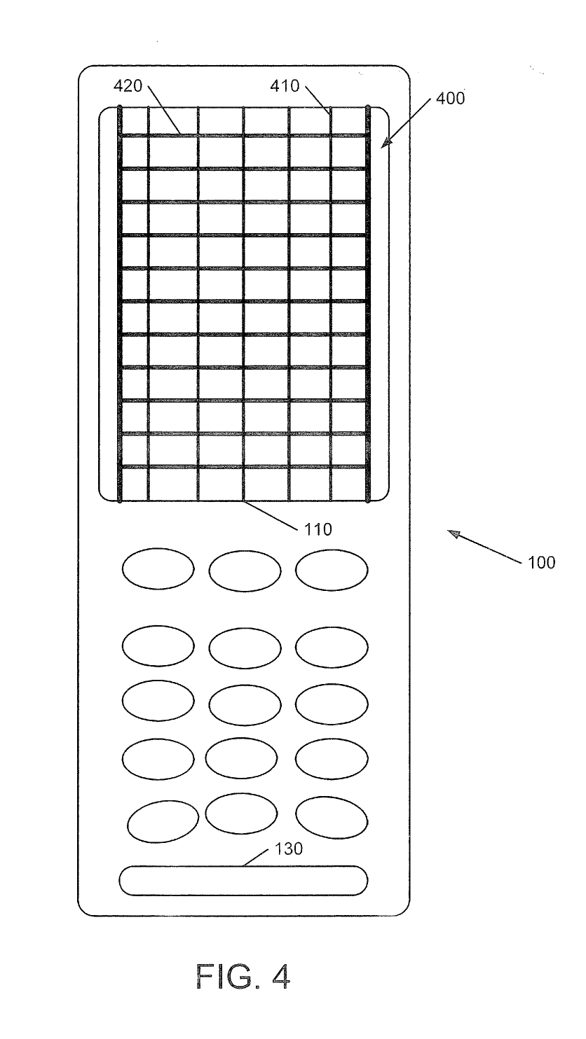

According to further embodiments of the present invention, inputs from a touch sensor may be used in conjunction with other control inputs of a handheld electronic device to provide additional control of a musical instrument. For example, referring to FIG. 4, the display 100 may be a touch-sensitive display that is operative to receive control inputs from contact with its surface. The control circuitry of the terminal 100, e.g., a control circuit along the lines of the control circuit 140 of FIG. 2, may be configured to generate on the display 110 a graphical display of a control interface of a musical instrument, such as a graphic depiction of a fretboard 400 of a stringed instrument, comprising frets 420 and strings 410. User input to the touch sensor 130 may be used, for example, to simulate strumming or picking of one or more of the strings 410, with musical notes being determined by placement of the user's fingertips (or a stylus or other tool) on the touch-sensitive display 110. For example, to provide chords, a user might place multiple fingertips at selected locations on the display 110 corresponding to selected notes of the chord, and may “strum” across the touch sensor 130 to cause generation of sounds corresponding to the selected chord. If the touch sensor 130 has an elongate form factor along the lines illustrated in FIG. 3, for example, “plucking” of the touch sensor 130 at a particular location along the length thereof corresponding to one of the strings 410 might be used to generate note or notes from one or more selected strings. Other characteristics of contact with the touch sensor 130, such as the force, speed and repetition rate at which the user contacts the sensor 130, may be used to induce other effects, such as vibrato, tremolo, glissando and the like.

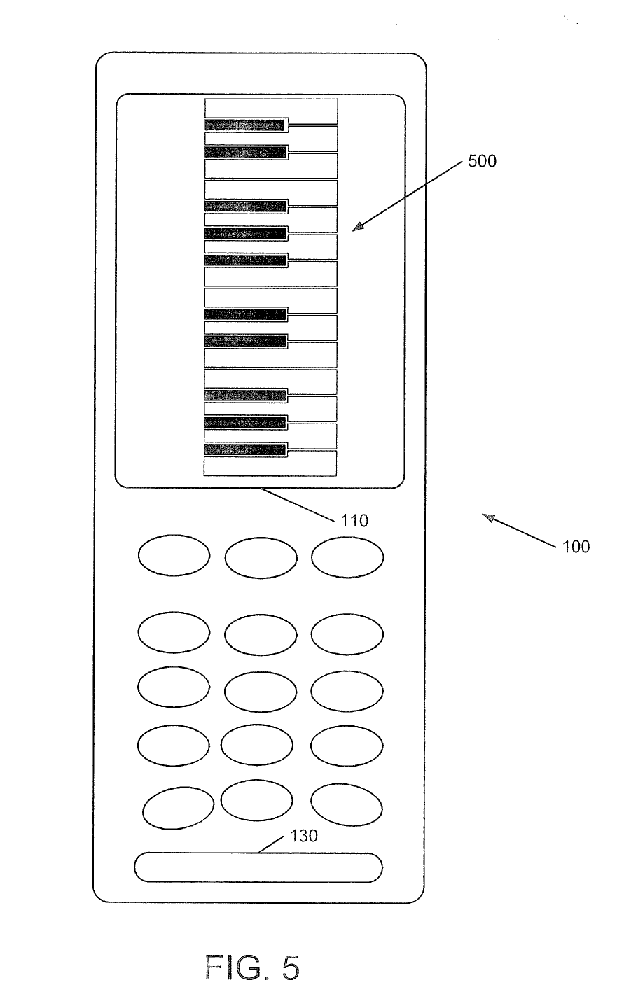

FIG. 5 illustrates another musical instrument implementation using inputs from a touch sensitive screen 110 and a touch sensor 130 according to further embodiments of the present invention. A control circuit of the terminal 100 may generate a graphical display of a keyboard 500 on the touch-sensitive display 110. User contact with the touch-sensitive display 110 relative to the depicted keyboard 500 may be used to play particular musical notes. User input to the touch sensor 130 may be used to control the generated note, e.g., to control volume and/or introduce additional effects.

It will be appreciated that the examples illustrated in FIGS. 4 and 5 are provided for purposes of illustration, and that the present invention is not limited to the particular musical instrument paradigms illustrated. In some embodiments of the present invention, for example, a handheld electronic device may be used to implement a musical instrument having different features, such as woodwind-, brass- or percussion-type devices, or hybrid devices having a mixture of features from different types of instruments.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. An electronic device, comprising:
a case configured to be supported in a user's hand while the device is in use;
a touch sensor mounted on the case; and
a control circuit supported by the case and configured to provide a user interface and to support user applications via the user interface, the control circuit further configured to support user operation of the handheld electronic device as a musical instrument that uses the touch sensor as a control input of the musical instrument.

2. The electronic device of claim 1, wherein the control circuit is configured to dynamically alter an audio signal produced by the musical instrument responsive to contact with the touch sensor.

3. The electronic device of claim 2, where the control circuit is configured to control a tone and/or a volume of the audio signal responsive to the contact with the touch sensor.

4. The electronic device of claim 1, wherein the control circuit is configured to cause the handheld electronic device to emulate a stringed instrument wherein contact with the touch sensor corresponds to contact with the strings of the emulated stringed instrument.

5. The electronic device of claim 1, further comprising a touch-sensitive display electrically coupled to the control circuit and wherein the control circuit is further configured to support user operation of the handheld electronic device as a musical instrument that uses the touch sensor and the touch-sensitive display as control inputs for the musical instrument.

6. The electronic device of claim 5, wherein the control circuit is configured to generate a graphical emulation of a control interface of a musical instrument on the touch-sensitive display and to generate an audio signal responsive to contact with the touch-sensitive display in relation to the graphical representation.

7. The device of claim 1, wherein the control circuit is further configured to control the user applications responsive to the touch sensor.

8. The device of claim 1, wherein the control circuit is further configured to utilize the touch sensor as a fingerprint sensor for a security function.

9. The device of claim 1, wherein the device comprises a mobile terminal, a personal digital assistant, an ultraportable computer and/or a media player.

10. A method of operating a handheld electronic device that provides user applications via a user interface that includes a touch sensor, the method comprising:
operating the handheld electronic device as a musical instrument that uses the touch sensor as a control input of the musical instrument.

11. The method of claim 10, wherein operating the handheld electronic device as a musical instrument comprises dynamically altering an audio signal produced by the musical instrument responsive contact with the touch sensor.

12. The method of claim 11, where dynamically altering an audio signal comprises controlling a tone and/or a volume of the audio signal responsive to the contact with the touch sensor.

13. The method of claim 10, wherein operating the handheld electronic device as a musical instrument comprises emulating a stringed instrument wherein contact with the touch sensor corresponds to contact with the strings of the emulated stringed instrument.

14. The method of claim 10, wherein the handheld electronic device further comprises a touch-sensitive display, and wherein operating the handheld electronic device as a musical instrument comprises operating the handheld electronic device as a musical instrument that uses the touch sensor and the touch-sensitive display as control inputs for the musical instrument.

15. The method of claim 14, further comprising generating a graphical emulation of a control interface of a musical instrument on the touch-sensitive display and generating an audio signal responsive to contact with the touch-sensitive display in relation to the graphical representation.

16. The method of claim 10, further comprising controlling the user applications of the handheld electronic device responsive to the touch sensor.

17. The method of claim 10, further comprising using the touch sensor as a fingerprint sensor for a security function of the handheld electronic device.

18. The method of claim 10, wherein the handheld electronic device comprises a mobile terminal, a personal digital assistant, an ultraportable computer and/or a media player.

19. A computer program product for operating a handheld electronic device, the computer program product comprising computer program code embodied in a computer-readable storage medium, the computer program code comprising:
program code configured to support user applications via a user interface that includes a touch sensor of the handheld electronic device; and
program code configured to support operation of the handheld electronic device as a musical instrument that uses the touch sensor as a control input of the musical instrument.

20. The computer program product of claim 19, wherein the program code configured to support operation of the handheld electronic device as a musical instrument that uses the touch sensor as a control input of the musical instrument is further configured to support user operation of the handheld electronic device as a musical instrument responsive to control inputs from a touch-sensitive display of the handheld electronic device.
